(19) United States
(12) Patent Application Publication
(10) Pub. No.: US 2018/0151733 A1
(43) Pub. Date: May 31, 2018

(54) CARBON-BASED INTERFACE FOR EPITAXIALLY GROWN SOURCE/DRAIN TRANSISTOR REGIONS

(71) Applicant: INTEL CORPORATION, Santa Clara, CA (US)

(72) Inventors: GLENN A. GLASS, Portland, OR (US); PATRICK H. KEYS, Portland, OR (US); HAROLD W. KENNEL, Portland, OR (US); RISHABH MEHANDRU, Portland, OR (US); ANAND S. MURTHY, Portland, OR (US); KARTHIK JAMBUNATHAN, Hillsboro, OR (US)

(73) Assignee: INTEL CORPORATION, Santa Clara, CA (US)

(21) Appl. No.: 15/575,011

(22) PCT Filed: Jun. 19, 2015
(86) PCT No.: PCT/US2015/036657

§ 371 Date: Nov. 17, 2017

(51) Int. Cl. H01L 29/78; H01L 29/165; H01L 29/167; H01L 29/06; H01L 29/08; H01L 29/66; H01L 27/088

(52) U.S. Cl. CPC H01L 29/7848; H01L 29/165; H01L 29/167; H01L 29/0603; H01L 29/42392; H01L 29/785; H01L 29/66795; H01L 27/0886; H01L 29/0847

(57) ABSTRACT

Techniques are disclosed for forming p-MOS transistors having one or more carbon-based interface layers between epitaxially grown S/D regions and the channel region. In some cases, the carbon-based interface layer(s) may comprise a single layer having a carbon content of greater than 20% carbon and a thickness of 0.5-8 nm. In some cases, the carbon-based interface layer(s) may comprise a single layer having a carbon content of less than 5% and a thickness of 2-10 nm. In some such cases, the single layer may also comprise boron-doped silicon (Si:B) or boron-doped silicon germanium (SiGe:B). In some cases, one or more additional interface layers may be deposited on the carbon-based interface layer(s), where the additional interface layer(s) comprises Si:B and/or SiGe:B. The techniques can be used to improve short channel effects and improve the effective gate length of a resulting transistor.

### BACKGROUND

Increased performance and yield of circuit devices on a substrate, including transistors, diodes, resistors, capacitors, and other passive and active electronic devices formed on a semiconductor substrate, are typically major factors considered during design, manufacture, and operation of those devices. For example, during design and manufacture or forming of metal-oxide-semiconductor (MOS) transistor semiconductor devices, such as those used in complementary metal-oxide-semiconductor (CMOS) devices, it is often desired to increase movement of electrons (carriers) in n-type MOS device (n-MOS) channels and to increase movement of positive charged holes (carriers) in p-type MOS device (p-MOS) channels. Typical CMOS transistor devices utilize silicon as the channel material for both hole and electron majority carrier MOS channels. Example devices under consideration include planar, fin-FET and nanowire geometries.

### BRIEF DESCRIPTION OF THE DRAWINGS

FIG. 1 illustrates a method of forming an integrated circuit, in accordance with various embodiments of the present disclosure.

FIGS. 2A-H illustrate example structures that are formed when carrying out the method of FIG. 1, in accordance with various embodiments of the present disclosure.

FIG. 2I shows a cross-sectional view about the plane A-A in FIG. 2H, in accordance with an embodiment of the present disclosure.

FIG. 3 shows a cross-sectional view about the plane A-A in FIG. 2H to illustrate multiple interface layers and/or a graded interface layer, in accordance with an embodiment of the present disclosure.

FIG. 4A illustrates an example integrated circuit including two transistor structures having finned configurations, in accordance with an embodiment of the present disclosure.

FIG. 4B illustrates an example integrated circuit including two transistor structures having nanowire configurations, in accordance with an embodiment of the present disclosure.

FIG. 4C illustrates an example integrated circuit including two transistor structures, one having a finned configuration and one having a nanowire configuration, in accordance with an embodiment of the present disclosure.

FIG. 5 illustrates a computing system implemented with integrated circuit structures or transistor devices formed using the techniques disclosed herein, in accordance with various embodiments of the present disclosure.

### DETAILED DESCRIPTION

Techniques are disclosed for forming p-MOS transistors having one or more carbon-based interface layers between epitaxially grown S/D regions and the channel region. In some cases, the carbon-based interface layer(s) may comprise a single layer having a carbon content of greater than 20% carbon and a thickness of 0.5-8 nm, and more specifically a thickness of approximately 1 nm. In some cases, the carbon-based interface layer(s) may comprise a single layer having a carbon content of less than 5% and a thickness of 2-10 nm, and more specifically 5-10 nm. In some such cases, the single layer may also comprise boron-doped silicon (Si:B) or boron-doped silicon germanium (SiGe:B). In some cases, where the carbon-based interface layers are exposed to heat treatment during one or more annealing processes, the carbon may spread out to surrounding layers. Accordingly, the carbon-based interface may occupy a narrower or wider region than originally deposited depending on the thermal history used to complete formation of the semiconductor device(s). For example, transistors formed using the techniques described herein may include an interface region between a Si channel region and replacement S/D regions including carbon on the order of 1E13 to 3E14 atoms per cm², or some other suitable amount based on the end use or target application. In some cases, one or more additional interface layers may be deposited on the carbon-based interface layer(s), where the additional interface layer(s) comprises Si:B and/or SiGe:B. Any such interface layers may have the content of one or more materials graded during the deposition of the layer. The techniques can be used to improve short channel effects and improve the effective gate length of a resulting transistor. Numerous variations and configurations will be apparent in light of this disclosure.

General Overview

When forming a transistor, epitaxially grown boron-doped silicon (Si:B) or boron-doped silicon germanium (SiGe:B) source/drain (S/D) regions can provide high stress for p-channel silicon (Si) MOS transistor devices to enhance mobility in the channel region. However, such boron-doped S/D regions cause a strong driving force for boron diffusion into the channel region during thermal treatments post S/D deposition. The boron diffusion results in a large diffusion tail in the channel region, causing the effective channel length to become shorter than that defined by the gate electrode. This in turn leads to high off-state source to drain leakage current flow and low threshold gate voltage (Vt). These characteristics, commonly referred to as “short channel effects”, are undesirable and manifest as degradation in overall transistor performance.

Thus, and in accordance with one or more embodiments of the present disclosure, techniques are disclosed for forming p-MOS transistors having one or more carbon-based interface layers between epitaxially grown S/D regions and the channel region. In some embodiments, the carbon-based interface layer(s) can be incorporated between an n-type doped or an undoped Si channel region and epitaxially grown Si:B or SiGe:B S/D regions. In some such embodiments, the carbon-based interface layer(s) may include: a single thin interface layer comprising greater than 20% carbon (C); a single interface layer comprising C content of up to 5% and one of Si:B and SiGe:B; a graded interface layer comprising C, Si, and Ge, where at least one of the percentage of C and Ge content are graded as the layer is deposited; and/or multiple stepped layers of SiGe:B:C, where at least one of the percentage of C and Ge content are increased/decreased in a step-wise manner. In some embodiments, one or more additional interface layers may be included with the carbon-based interface layer between the Si channel region and the replacement S/D regions. In some such embodiments, the additional interface layer(s) may include: a single layer of boron-doped Si (Si:B); a single layer of SiGe:B, where the Ge content in the interface layer is less than that in the resulting SiGe:B S/D regions; a graded layer of SiGe:B, where the Ge content in the alloy starts at a low percentage (or 0%) and is increased to a higher percentage; or multiple stepped layers of SiGe:B, where the Ge content in the alloy starts at a low percentage (or 0%) and is increased to a higher percentage. For ease of description, SiGe may be referred to herein as Si₁₋ₓGeₓ where x represents the percentage of Ge in the SiGe alloy (in decimal format) and 1-x represents the percentage of Si in the SiGe alloy (in decimal format). For example, if x is 0.3, then the SiGe alloy comprises 30% Ge and 70% Si, or if x is 0, then the SiGe alloy comprises 0% Ge and 100% Si, or if x is 0.6, then the SiGe alloy comprises 60% Ge and 40% Si, or if x is 1, then the SiGe alloy comprises 100% Ge and 0% Si. Accordingly, Si may be referred to herein as SiGe (Si₁₋ₓGeₓ where x is 0) and Ge may be referred to herein as SiGe (Si₁₋ₓGeₓ where x is 1).

As previously described, in some embodiments, the carbon-based interface layer(s) may include a single layer comprising C at a content value of greater than 20%. In some such embodiments, the single carbon-based interface layer may have a thickness of 0.5-8 nm, and more specifically a thickness of ˜1 nm. Further, in some such embodiments, one or more additional interface layers may be deposited between the carbon-based interface layer and the replacement S/D regions. For example, the additional interface layer(s) may comprise a single Si:B layer, a single SiGe:B layer, a graded from low to high percentage of Ge content SiGe:B layer, or multiple layers of SiGe:B with increasing percentage of Ge content (and where the first layer may include 0% Ge and thus comprise Si:B). In some embodiments, the carbon-based interface layer(s) may include a single layer comprising C content of up to 5% and one of Si:B and SiGe:B. In some such embodiments, the single carbon-based interface layer may have a thickness of 2-10 nm, and more specifically a thickness of 5-10 nm. Further, in some such embodiments, the carbon-based interface layer may encompass the entire interface region between the Si channel and replacement S/D regions, particularly when the layer has a thickness of 8-10 nm, for example. As used herein, note that “single layer” refers to a continuous layer of the same material and may have an arbitrary thickness ranging from a monolayer to a relatively thick layer in the nanometer range (or thicker, if so desired). Further note that such a single layer may be deposited, for example, so as to actually comprise a plurality of sub-layers of common material that make up the overall single layer of that common material. Further note that one or more components of that single layer may be graded from a first concentration to a second concentration during the deposition process.

In some embodiments, the carbon-based interface layer(s) may include a single layer comprising C content between (and inclusive of) 5% and 20%. In some embodiments, multiple carbon-based interface layers and/or a graded carbon-based interface layer may be included in an interface region between the Si channel region and replacement S/D regions, as will be apparent in light of the present disclosure. In some such embodiments, the percentage of C content in the multiple layers may decrease as the layers are deposited, such that the layer nearest the Si channel comprises the highest percentage of C content in the interface region and the layer nearest the replacement S/D regions comprises the lowest percentage of C content in the interface region. Further, in some such embodiments, the percentage of C content in the graded layers may be decreased during the deposition, such that the portion or side of the interface region nearest the Si channel comprises the highest percentage of C content in the interface region and the portion or side nearest the replacement S/D regions comprises the lowest percentage of C content in the interface region. In some embodiments, the carbon-based interface layer(s) and, where included, the additional interface layer(s) (as variously described herein) may have a substantially conformal growth pattern. Such a substantially conformal growth pattern may include that the thickness of a portion of an interface layer that is between the Si channel region and the respective replacement S/D region is substantially the same (e.g., within 1 or 2 nm tolerance) as the thickness of a portion of the interface layer that is between the respective replacement S/D region and the substrate.

Numerous benefits can be achieved by the inclusion of one or more carbon-based interface layers between the Si channel region and Si:B/SiGe:B S/D regions of a p-MOS transistor. The presence of carbon inhibits the diffusion of boron in Si based layers. Therefore, boron diffusion into the channel region can be decreased (and kept to an overall minimum, in some embodiments), attaining improved on-state current flow as well as improved short channel effects, as compared to a similar transistor not including the carbon-based interface layer(s). In some cases, a reduction (improvement) of 1.5 nm or greater in the extent of boron diffusion into the channel region per side can be achieved with typical thermal treatments. Accordingly, effective gate length can be maintained and improved compared to architecture that does not include one or more carbon-based interface layers, such as an effective gate length improvement of 3 or more nm, depending on the particular configuration. Performance gains from the inclusion of one or more carbon-based interface layers have been observed in a linear regime and at a gate bias of 0.6V of a 13% increase in drive current. However, greater improvements may be achieved depending on the particular configuration used. The techniques can be adjusted based on the end use or target application, such as focusing on minimizing boron diffusion into the channel region by only including one or more carbon-based layers in the interface region versus improving external resistance by increasing doping in the interface and/or S/D regions but using a carbon-based interface layer(s) to help with boron diffusion versus incorporating carbon in a Si:B or graded SiGe:B interface layer to improve short channel effects while gaining the benefit from the reduced heterojunction barrier height at the interface of the channel and S/D regions (e.g., improved on-state current due to lower thermionic emission barrier).

Upon analysis (e.g., using scanning/transmission electron microscopy (SEM/TEM), composition mapping, secondary ion mass spectrometry (SIMS), atom probe imaging, 3D tomography, etc.), a structure or device configured in accordance with one or more embodiments will effectively show one or more carbon-based interface layers located between an n-type doped or undoped Si channel and replacement S/D regions (e.g., Si:B or SiGe:B S/D regions). For example, the presence and location of C can be measured using SIMS in conjunction with structural information from TEM or atom probe techniques (e.g., 3D tomography). Such an example would show the presence of carbon in one or more layers between the Si channel region and respective replacement S/D regions. Detection of the carbon-based interface layer(s) may also be achieved by measuring whether there is a B diffusion tail in the Si channel region and the size of that tail. This is because conventional p-MOS transistor devices that include epitaxially grown SiGe:B S/D regions may utilize boron out-diffusion from thermal cycles post SiGe:B deposition to provide sufficient doping across the hetero-interface barrier existing between the Si channel region and the S/D regions. However, such a conventional process results in a large diffusion tail going into the Si channel region, which causes negative short channel effects, thereby degrading overall device performance. A p-MOS transistor device formed with one or more carbon-based interface layers using the techniques variously described herein can be formed to improve short channel effects by maintaining effective gate length and/or improve external resistance in the S/D regions by allowing increased boron-doping amounts. Numerous configurations and variations will be apparent in light of this disclosure.

Architecture and Methodology

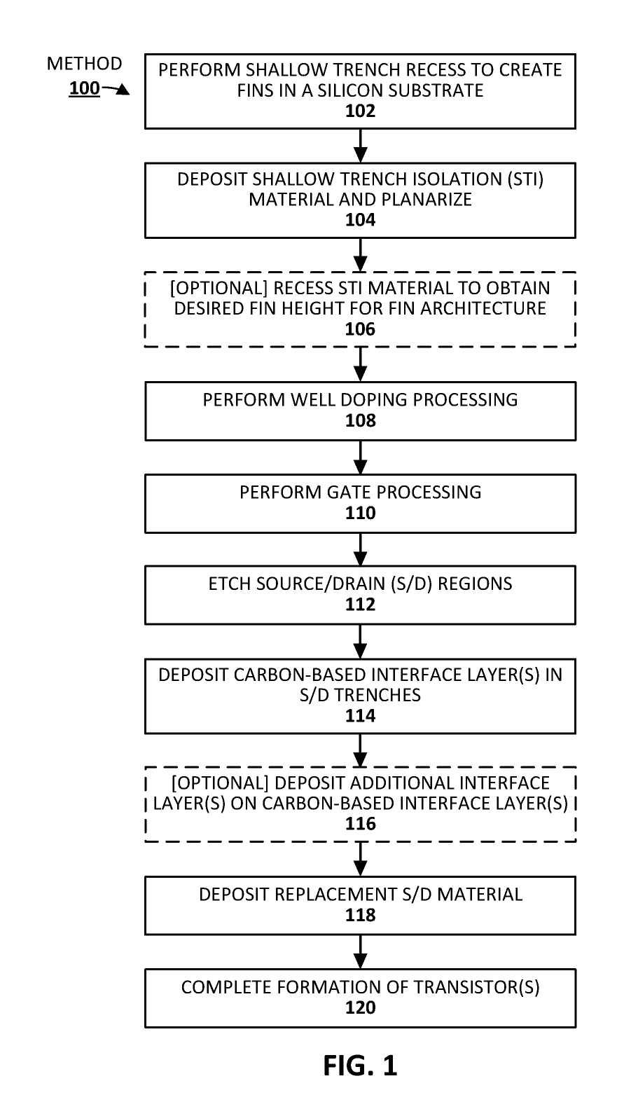

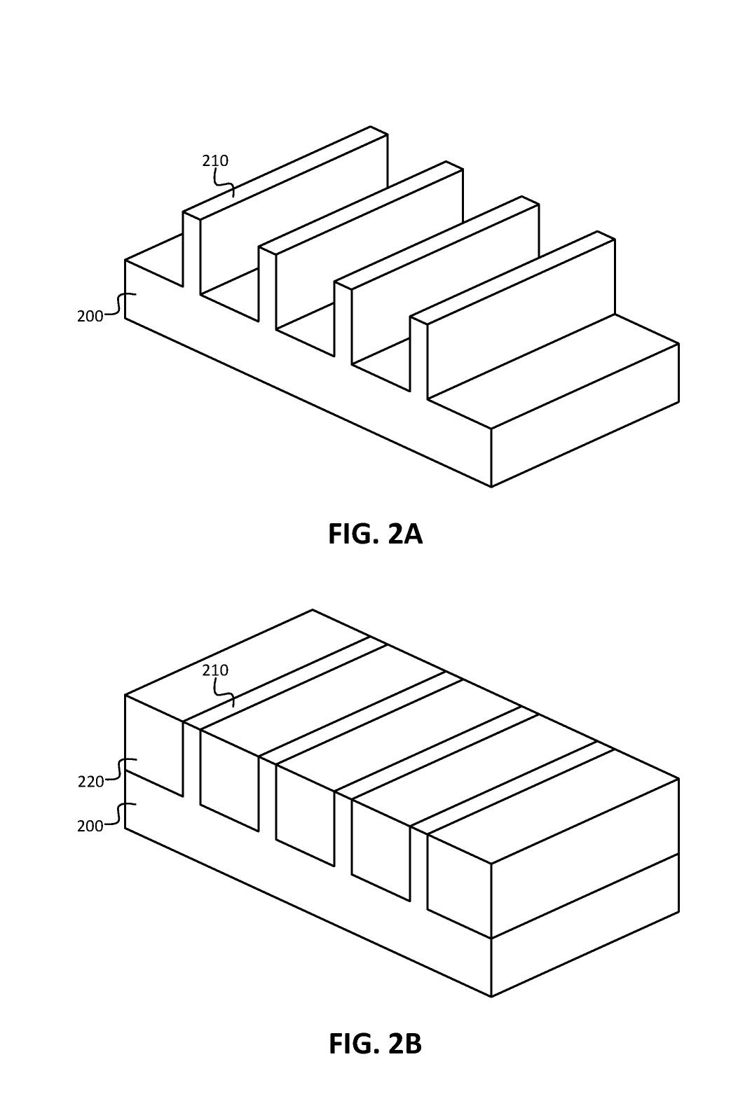

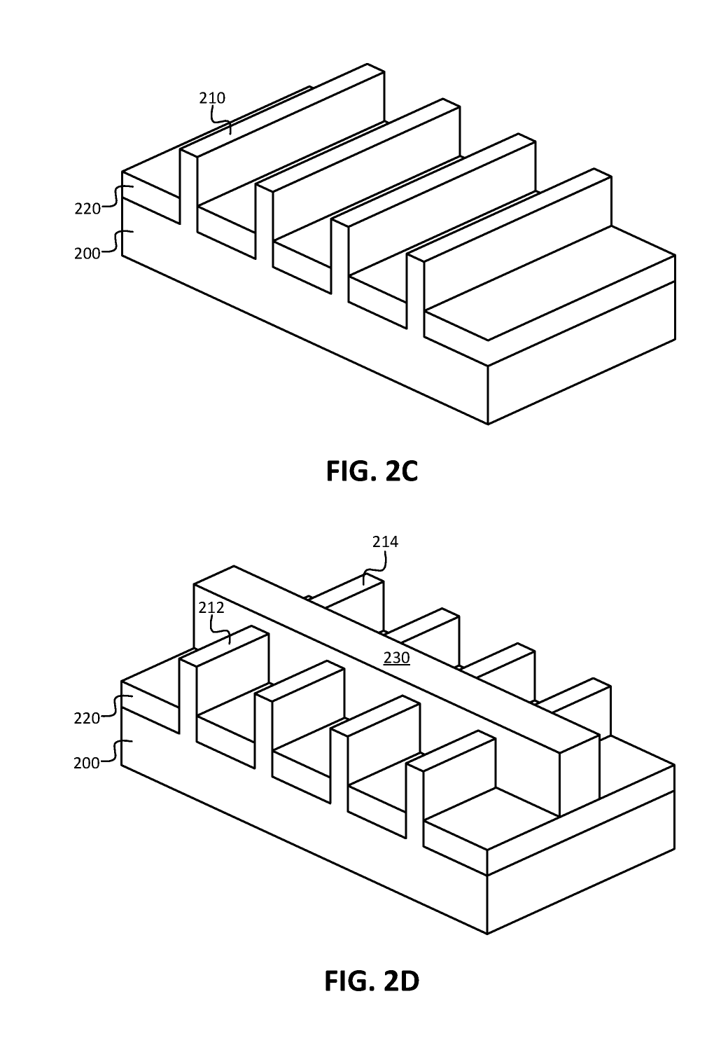

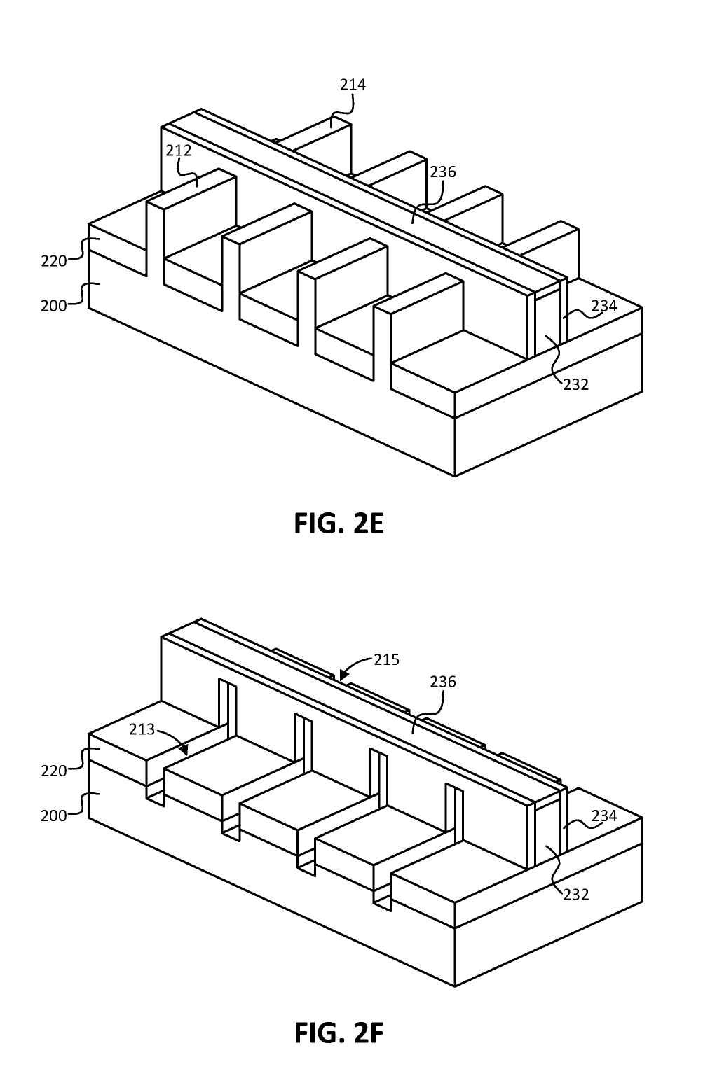

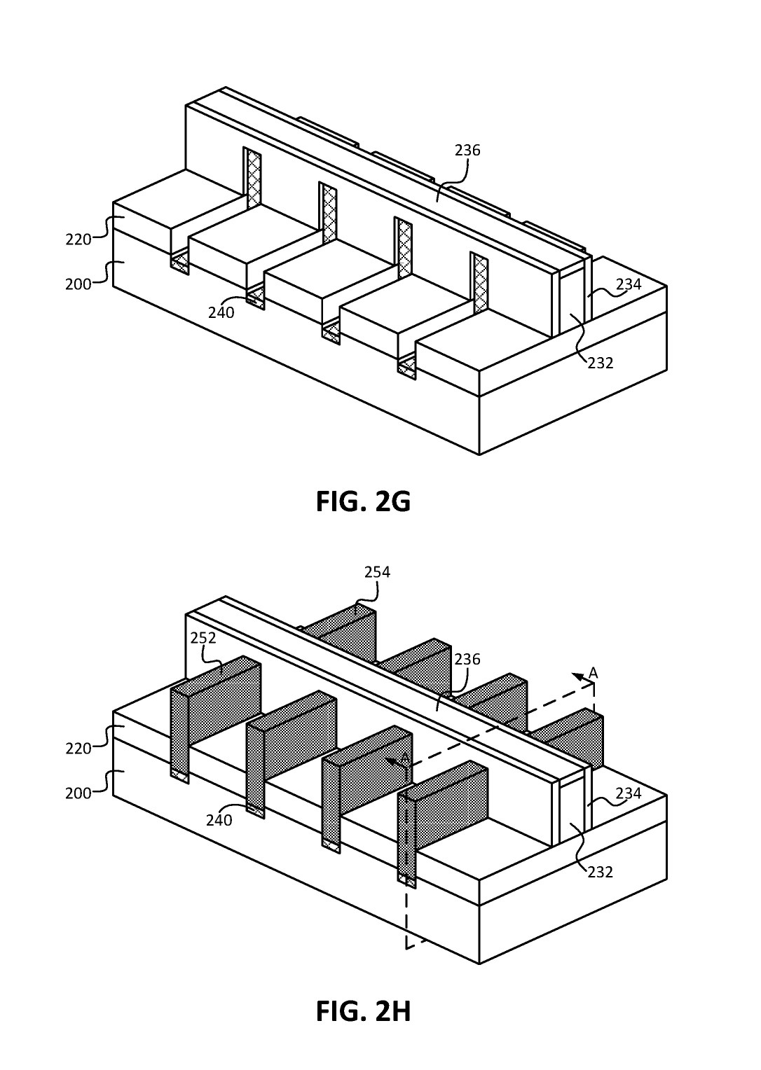

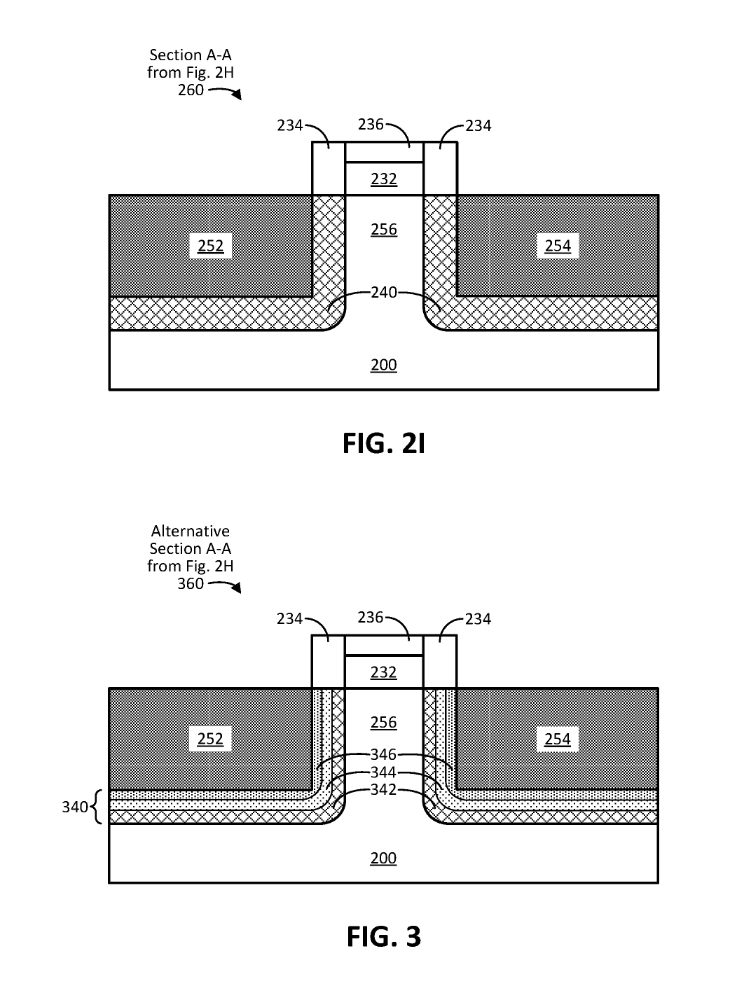

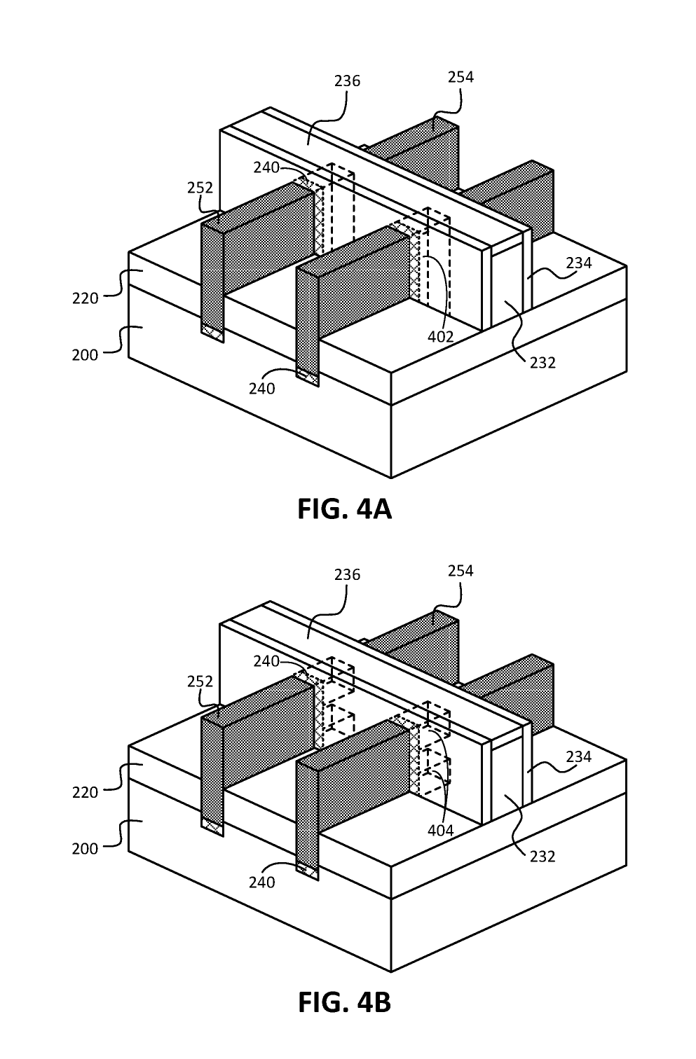

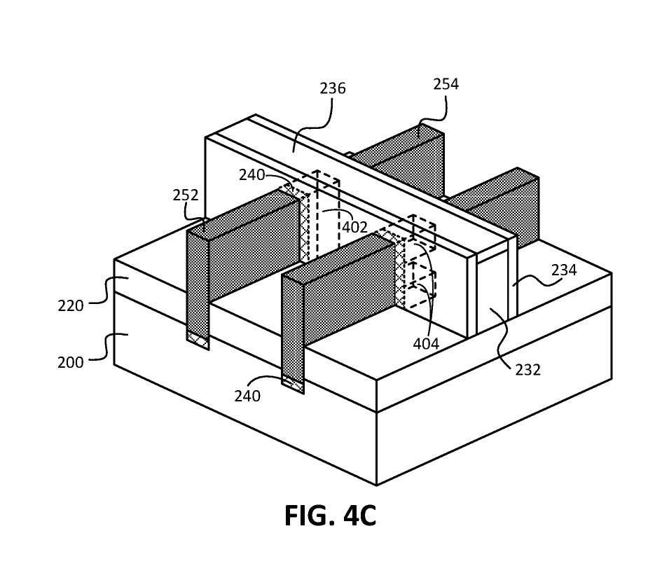

FIG. 1 illustrates a method 100 of forming an integrated circuit, in accordance with one or more embodiments of the present disclosure. FIGS. 2A-I illustrate example structures that are formed when carrying out method 100 of FIG. 1, in accordance with various embodiments. As will be apparent in light of the structures formed, method 100 discloses techniques for forming a transistor having a channel region, epitaxially grown S/D regions, and one or more interface layers therebetween (at least one of which is a carbon-based interface layer). FIG. 3 illustrates an example structure similar to the structure of FIG. 21, including multiple interface layers and/or a graded interface layer, in accordance with an embodiment. The structures of FIGS. 2A-I are primarily depicted and described herein in the context of forming finned transistor configurations (e.g., tri-gate or fin-FET), for ease of illustration. However, the techniques can be used to form planar, dual-gate, finned, and/or nanowire (or gate-all-around or nanoribbon) transistor configurations, or other suitable configurations, as will be apparent in light of this disclosure. For example FIGS. 4A and 4C illustrate example structures including finned transistor configurations and FIGS. 4B and 4C illustrate example structures including nanowire transistor configurations, as will be discussed in more detail below.

As can be seen in FIG. 1, method 100 includes performing 102 shallow trench recess to create fins 210 in a Si substrate 200, thereby forming the example resulting structure shown in FIG. 2A, in accordance with an embodiment. In some embodiments, substrate 200 may be: a bulk substrate comprising Si; a Si on insulator (SOI) structure where the insulator material is an oxide material or dielectric material or some other electrically insulating material; or some other suitable multilayer structure where the top layer comprises Si. Fins 210 can be formed 102 from substrate 200 using any suitable etch techniques, such as one or more of the following processes: wet etching, dry etching, lithography, masking, patterning, exposing, developing, resist spinning, ashing, or any other suitable processes. In some instances, shallow trench recess 102 may be performed in-situ/without air break, while in other instances, the process 102 may be performed ex-situ.

Fins 210 (and the trenches therebetween) may be formed to have any desired dimensions, depending upon the end use or target application. Although four fins are shown in the example structure of FIG. 2A, any number of fins can be formed as desired, such as one fin, two fins, twenty fins, one hundred fins, one thousand fins, one million fins, etc. In some cases, all of the fins 210 (and the trenches therebetween) may be formed to have similar or exact dimensions (e.g., as shown in FIG. 2A), while in other cases, some of the fins 210 (and/or trenches therebetween) may be formed to have different dimensions, depending upon the end use or target application. In some embodiments, shallow trench recess 102 may be performed to create fins having height to width ratios of 3 or more and such fins may be used for non-planar transistor configurations, for example. In some embodiments, shallow trench recess 102 may be performed to create fins having height to width ratios of 3 or less and such fins may be used for planar transistor configurations, for example. Various different fin geometry will be apparent in light of the present disclosure.

Method 100 of FIG. 1 continues with depositing 104 shallow trench isolation (STI) material 220 and planarizing the structure to form the example resulting structure shown in FIG. 2B, in accordance with an embodiment. Deposition 104 of STI material 220 can be performed using any suitable techniques, such as chemical vapor deposition (CVD), plasma enhanced CVD (PECVD), atomic layer deposition (ALD), spin-on processing, and/or any other suitable process. In some instances, the surface of substrate 200 and fins 210 to be deposited on may be treated (e.g., chemical treatment, thermal treatment, etc.) prior to deposition of the STI material 220. STI material 220 may comprise any suitable insulating material, such as one or more dielectric or oxide materials (e.g., silicon dioxide).

Method 100 of FIG. 1 continues with optionally recessing 106 the STI material 220 to obtain a desired fin height for the resulting fin architecture, thereby forming the example resulting structure shown in FIG. 2C, in accordance with an embodiment. Recess 106 of STI material 220 may be performed using any suitable technique, such as one or more wet and/or dry etching processes, or any other suitable processes. In some instances, recess 106 may be performed in-situ/without air break, while in other instances, the recess 106 may be performed ex-situ. In some embodiments, recess 106 may be skipped, such as in the case where the resulting desired transistor architecture is planar, for example. Accordingly, recess 106 is optional. In some embodiments, recess 106 may be performed when the resulting desired transistor architecture is non-planar (e.g., finned or nanowire/nanoribbon architecture). Method 100 of FIG. 1 continues with performing 108 well doping processing, in accordance with an embodiment. Well doping 108 may be performed using any standard techniques, depending on the end use or target application. For example, in the case of forming p-MOS transistors, an n-type dopant may be used to dope at least the portion of the Si fin 210 to be later used as a p-MOS channel region. Example n-type dopants include phosphorous (P) and arsenic (As), just to name a few examples. Note that well doping 108 may be performed earlier in method 100, depending upon the techniques used.

Method 100 of FIG. 1 continues with performing 110 gate 230 processing to form the example resulting structure shown in FIG. 2D, in accordance with an embodiment. Gate stack 230 may be formed using any standard techniques. For example, gate stack 230 may include gate electrode 232 shown in FIG. 2E and a gate dielectric (not show for ease of illustration) formed directly under gate electrode 232. The gate dielectric and gate electrode 232 may be formed using any suitable technique and the layers may be formed from any suitable materials. The gate dielectric can be, for example, any suitable oxide such as SiO₂ or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used. In general, the thickness of the gate dielectric should be sufficient to electrically isolate the gate electrode from the source and drain contacts. Further, the gate electrode 232 may comprise a wide range of materials, such as polysilicon, silicon nitride, silicon carbide, or various suitable metals or metal alloys, such as aluminum (Al), tungsten (W), titanium (Ti), tantalum (Ta), copper (Cu), titanium nitride (TiN), or tantalum nitride (TaN), for example.

In some embodiments, the gate stack 230 may be formed during a replacement metal gate (RMG) process, and such a process may include any suitable deposition technique (e.g., CVD, PVD, etc.). Such a process may include dummy gate oxide deposition, dummy gate electrode (e.g., poly-Si) deposition, and patterning hardmask deposition. Additional processing may include patterning the dummy gates and depositing/etching spacer 234 material. Additional processing may also include tip doping, depending on the end use or target application. Following such processes, the method may continue with insulator deposition, planarization, and then dummy gate electrode and gate oxide removal to expose the channel region of the transistors. Following opening the channel region, the dummy gate oxide and electrode may be replaced with, for example, a hi-k dielectric and a replacement metal gate, respectively. As can be seen in the example structure of FIG. 2E, spacers 234 were formed using standard techniques. Spacers 234 may be formed to, for example, protect the gate stack (such as gate electrode 232 and/or gate dielectric) during subsequent processing. Further note that the example structure of FIG. 2E includes hardmask 236 formed using standard techniques. Hardmask 236 may be formed to, for example, protect the gate stack (such as gate electrode 232 and/or gate dielectric) during subsequent processing.

The gate stack defines channel regions as well as source and drain regions of subsequently formed transistors, where the channel region is underneath the gate stack and the source/drain (S/D) regions are located on either side of the channel region. For example, the portion of fins 210 underneath gate stack 230 in FIG. 2D can be used for transistor channel regions and the portion of fins 212 and 214 on either side of gate stack 230 can be used for transistor S/D regions. Note that 212 could be used either for the source region or the drain region, and 214 can be used for the other region, based on the resulting configuration. Accordingly, once the gate stack is fabricated, the S/D regions 212 and 214 can be processed.

Method 100 of FIG. 1 continues with etching 112 S/D regions 212 and 214 to form the resulting example structure of FIG. 2F, in accordance with an embodiment. As can be seen in the example structure of FIG. 2F, the S/D regions 212 and 214 were lithographically patterned to form trenches 213 and 215, respectively. Etch 112 can be performed using any suitable techniques, such as one or more wet and/or dry etching processes, or any other suitable processes. In some instances, etch 112 may be performed in-situ/without air break, while in other instances, the etch 112 may be performed ex-situ. Note that in this example embodiment, fin regions 212 and 214 were etched to form trenches 213 and 215. However, in structures formed for planar transistor configurations (e.g., where recess 106 is not performed), the source/drain region diffusion areas may instead be etched 112 and removed to form trenches.

Method 100 of FIG. 1 continues with depositing 114 one or more carbon-based interface layers 240 in the S/D trenches 213 and 215 to form the resulting example structure of FIG. 2G, in accordance with an embodiment. Method 100 of FIG. 1 continues with depositing 118 replacement S/D material 252 and 254 on interface layer(s) 240 in the S/D regions to form the resulting example structure of FIG. 2H, in accordance with an embodiment. In such an embodiment, the replacement S/D material may be boron-doped silicon (Si:B) or boron-doped silicon germanium (SiGe:B). In some embodiments, method 100 of FIG. 1 optionally includes depositing 116 one or more additional interface layers between the carbon-based interface layer(s) 240 and the respective replacement S/D material 252 and 254. FIG. 2I shows a cross-sectional view 260 about the plane A-A in FIG. 2H to illustrate a single carbon-based interface layer 240, in accordance with an embodiment. FIG. 3 shows a cross-sectional view 360 about the plane A-A in FIG. 2H to illustrate multiple interface layers and/or a graded interface layer 340, in accordance with an embodiment. As can be understood, layer(s) 240 is referred to as interface layer(s), because the one or more layers 240 are located at the interface of the Si channel region 256 and the replacement S/D regions 252 and 254 (e.g., as can be seen in FIG. 21). Depositions 114, 116 and 118 may include any deposition process described herein (e.g., CVD, RTCVD, ALD, etc.), or any other suitable deposition or growth processes, depending upon the end use or target application. For example, depositions 114, 116, and 118 may be performed in-situ/without air break or ex-situ. As will be discussed in more detail below, deposition 114 may include depositing a single carbon-based interface layer, multiple carbon-based interface layers, and/or a graded carbon-based interface layer (where the percentage of C content is decreased during the deposition process).

In some embodiments, the carbon-based interface layer(s) may include a single layer comprising C at a content value of greater than 20%. For example, interface layer 240 in FIGS. 2G-I may be a single layer comprising C at a content of greater than 20%. In some such embodiments, the single carbon-based interface layer may have a thickness of 0.5-8 nm, and more specifically a thickness of ˜1 nm. A specific example of conditions used to fabricate such a single carbon-based interface layer includes using monomethyl silane (MMS) gas and dichlorosilane (DCS) gas, both at flows of 100 sccm, at 750 C and 100 Torr.

In some embodiments, the carbon-based interface layer(s) may include a single layer comprising C content of up to 5% and one of Si:B and SiGe:B. For example, interface layer 240 in FIGS. 2G-I may be a single layer of carbon-doped silicon (Si:C), carbon-doped silicon germanium (SiGe:C), Si:B:C, or SiGe:B:C, where the C content in the layer 240 is up to 5%. In some such embodiments, the single carbon-based interface layer may have a thickness of 2-10 nm, and more specifically a thickness of 5-10 nm. Further, in some such embodiments, the carbon-based interface layer may encompass the entire interface region between the Si channel and replacement S/D regions, particularly when the layer has a thickness of 8-10 nm, for example. However, some embodiments including a carbon-based interface layer comprising C content of up to 5% may include additional interface layers. For example, the additional interface layer(s) may comprise a single Si:B layer, a single SiGe:B layer, a graded from low to high percentage of Ge content SiGe:B layer, or multiple layers of SiGe:B with increasing percentage of Ge content (and where the first layer may include 0% Ge and thus comprise Si:B). The amount of boron doping in the carbon-based interface layer(s) can be selected as desired based on the end result or target application. Note that carbon-based interface layer(s) discussed herein may include a higher, lower, or equal amount of boron doping as compared to the amount of boron doping in the replacement S/D regions or as compared to the amount of boron doping in optional additional interface layers. Further note that in some embodiments, the carbon-based interface layer(s) may not be boron doped.

In some embodiments, the carbon-based interface layer(s) may include a single layer comprising C content between (and inclusive of) 5% and 20%. For example, interface layer 240 in FIGS. 2G-I may be a single layer comprising C at a content greater than or equal to 5% and less than or equal to 20%. In some embodiments, multiple carbon-based interface layers and/or a graded carbon-based interface layer may be included in an interface region between the Si channel region and replacement S/D regions. For example, interface layer 340 in FIG. 3 may comprise a single graded layer comprising C where the percentage of C content decreases from section 342 to section 344 to section 346. In another example, interface layers 340 in FIG. 3 may comprise multiple layers comprising C where the percentage of C content decreases from layer 342 to layer 344 to layer 346. In some such embodiments, the percentage of C content in the multiple layers may decrease as the layers are deposited, such that the layer nearest the Si channel comprises the highest percentage of C content in the interface region and the layer nearest the replacement S/D regions comprises the lowest percentage of C content in the interface region. Further, in some such embodiments, the percentage of C content in the graded layers may be decreased during the deposition, such that the portion/side of the interface region nearest the Si channel comprises the highest percentage of C content in the interface region and the portion/side nearest the replacement S/D regions comprises the lowest percentage of C content in the interface region.

In some embodiments, the carbon-based interface layer(s) and, where included, the additional interface layer(s) (as variously described herein) may have a substantially conformal growth pattern. Such a substantially conformal growth pattern may include that the thickness of a portion of an interface layer that is between the Si channel region and the respective replacement S/D region is substantially the same (e.g., within 1 or 2 nm tolerance) as the thickness of a portion of the interface layer that is between the respective replacement S/D region and the substrate. In some embodiments, where the carbon-based interface layers are exposed to heat treatment during one or more annealing processes, the carbon may spread out to surrounding layers. Accordingly, the carbon-based interface may occupy a narrower or wider region than originally deposited depending on the thermal history used to complete formation of the semiconductor device(s). For example, transistors formed using the techniques described herein may include an interface region between a Si channel region and replacement S/D regions including carbon on the order of 1E13 to 3E14 atoms per cm², or some other suitable amount based on the end use or target application.

As previously described, in some embodiments, one or more additional interface layers may optionally be deposited 116 on the carbon interface layer(s) before the replacement S/D material 252, 254 is deposited 118. In some such embodiments, a single additional interface layer of Si:B may be deposited in the interface region (e.g., in interface region 340 in FIG. 3). For example, layer(s) 342 of FIG. 3 may comprise one or more carbon-based interface layers (as variously described herein) and sections 344 and 346 may comprise a single layer of Si:B. In some such embodiments, the single Si:B interface layer may have a thickness of 1-10 nm, and more specifically a thickness of 2-5 nm, or some other suitable thickness depending on the end use or target application. The amount of boron doping in the Si:B or SiGe:B interface layer can be selected as desired based on the end result or target application, such as a doping level of approximately 1.0E20 or some other suitable amount. Note that the Si:B interface layer may include a higher, lower, or equal amount of boron doping as compared to the amount of doping in the replacement S/D regions 252 and 254. A specific example of conditions used to fabricate such a single Si:B interface layer includes a selective deposition process using dichlorosilane and/or silane, diborane, hydrochloric acid, and hydrogen carrier gas in a CVD reactor at a pressure of 20 Torr and a temperature of 700-750 degrees Celsius for example resulting in a layer with a boron concentration at or near 2E20 atoms/cm³.

In some embodiments, the additional interface layer(s) may include a single layer of boron-doped silicon germanium (SiGe:B). For example, layer(s) 342 of FIG. 3 may comprise one or more carbon-based interface layers (as variously described herein) and sections 344 and 346 may comprise a single layer of SiGe:B. In some such embodiments, the single SiGe:B interface layer may have a thickness of 1-10 nm, and more specifically a thickness of 2-5 nm, or some other suitable thickness depending on the end use or target application. Further, in some such embodiments, the Ge content in the interface layer may be less than that in the resulting S/D regions 252 and 254, when the S/D regions comprise SiGe:B. In an example embodiment, the Ge content in the interface layer may be 5-30% lower than the Ge content in the S/D regions, such as 15-20% lower. For example, if the resulting SiGe:B S/D regions comprise 30% Ge (Si₁₋ₓGeₓ:B where x is 0.3), then the SiGe:B interface layer may comprise 15% Ge (Si₁₋ₓGeₓ:B where x is 0.15). The amount of boron doping in the SiGe:B interface layer can be selected as desired based on the end result or target application. Note that the SiGe:B interface layer may include a higher, lower, or equal amount of boron doping as compared to the amount of doping in the SiGe:B S/D regions. A specific example of conditions used to fabricate such a single SiGe:B interface layer includes a selective deposition process using dichlorosilane and/or silane, germane, diborane, hydrochloric acid, and hydrogen carrier gas in a CVD reactor at a pressure of 20 Torr and a temperature of 700 degrees Celsius for example resulting in a layer with a boron concentration at or near 2E20 atoms/cm³ and a Ge percentage of 30-65%. In some embodiments, the additional interface layer(s) may include multiple layers and/or a graded layer having an increasing percentage of Ge. For example, layer(s) 342 of FIG. 3 may comprise one or more carbon-based interface layers (as variously described herein) and sections 344 and 346 may comprise a single graded layer of SiGe:B where the Ge percentage increases from section 344 to section 346. In such an example, the percentage of Ge content may be graded from a low starting percentage or a starting percentage of 0 (in other words, starting with Si:B) to a higher percentage that is equal to or less than the percentage of Ge content in the replacement S/D regions 252 and 254. Any amount of grading can be used, depending on the end use or target application. In another example, layer (s) 342 may comprise one or more carbon-based interface layer (as variously described herein) 344 and 346 may comprise multiple layers of SiGe:B where the Ge percentage increases from layer 344 to layer 346. In such an example, the percentage of Ge content may be stepped up from a low starting percentage or a starting percentage of 0 (in other words, starting with Si:B) in layer 344 to a higher percentage in layer 346 that is equal to or less than the percentage of Ge content in the replacement S/D regions 252 and 254. Any number of stepped layers can be used, depending on the end use or target application.

Note that the thicknesses, C content, Ge content, and boron-doping of the interface layers or graded sections may be selected as desired depending on the end use or target application. For example, the Ge content in the interface region (e.g., region 340 of FIG. 3) may be increased from 0% to 30% over a range of 2-10 nm. In such an example, the increase may be stepped in multiple layers such that, for example, layer 342 includes 0% Ge content (e.g., Si:C or Si:B:C), layer 344 includes 15% Ge content (e.g., Si₁₋ₓGeₓ:B:C or Si₁₋ₓGeₓ:B, where x is 0.15), and layer 346 includes 30% Ge content (e.g., Si₁₋ₓGeₓ:B:C or Si₁₋ₓGeₓ:B, where x is 0.3). In another example, the increase may be graded over the different sections, such that section 342 includes 0-10% Ge content, section 344 includes 10-20% Ge content, and section 346 includes 20-30% Ge content. In some embodiments, the percentage of Ge content in one interface layer may be determined based on the percentage of Ge content in another interface layer. For example, in the case of FIG. 3, the interface layer 346 nearest the corresponding S/D region 252 or 254 may be 5, 10, 15, 20, or 25% or some other suitable percentage higher than the Ge content in the interface layer 342 nearest the channel region 256. In some embodiments, the Ge content of the interface layer(s) may be based on the Ge content of the SiGe:B S/D regions. For example, the interface layer(s) may include a Ge content grading from a low Ge content (e.g., 0, 5, 10, or 15%) to the Ge content in the SiGe:B S/D regions (e.g., 30, 40, 50, 60, or 70%) or to a percentage of Ge content of 5, 10, 15, or 20% , or some other suitable percentage lower than the percentage of Ge content in the SiGe:B S/D regions.

In some embodiments, deposition 114 and/or 116 may include a substantially conformal growth pattern, such as can be seen in FIGS. 21 and 3. Substantially conformal includes that the thickness of a portion of an interface layer that is between the channel region 256 and the S/D regions 252/254 (e.g., the vertical portion of layer 240 in FIG. 21, the vertical portion of layers 342, 344, 346 in FIG. 3) is substantially the same (e.g., within 1 or 2 nm tolerance) as the thickness of a portion of the interface layer that is between the S/D regions and the substrate 200 (e.g., the horizontal portion of layer 240 in FIG. 2I, the horizontal portion of layers 342, 344, 346 in FIG. 3). Note that in embodiments including multiple interface layers, the layers may have substantially the same or varying thicknesses. As previously described, the interface layer(s) may include a graded layer (where the percentage content of one or more materials is graded throughout a single layer) or multiple stepped layers (where the percentage content of one or more materials is increased/decreased in a step-wise manner from one layer to another). In such instances, a single graded layer and multiple stepped layers may be visually similar. However, in some cases, adjustments of the graded material (e.g., the decrease of C content, the increase of Ge content, etc.) made through a graded layer may be more gradual than in stepped layers, for example. Further note that in embodiments including a graded interface layer, the percentage of material content grading (e.g., C or Ge grading) may or may not be consistent throughout the layer. Also note that in some instances, multiple interface layers may include some degree of content grading of one or more materials and a graded interface layer may include some degree of stepped content of one or more materials that may appear to be different layers. In other words, the transition in the percentage of material content throughout the interface layer(s) may be gradual, stepped, or some combination thereof.

Method 100 of FIG. 1 continues with completing 120 formation of one or more transistors. Completion 120 may include various processes, such as encapsulation with an insulator material, replacement metal gate (RMG) processing, contact formation, and/or back-end processing. For example, contacts may be formed the S/D regions using, for example, a silicidation process (generally, deposition of contact metal and subsequent annealing). Example source drain contact materials include, for example, tungsten, titanium, silver, gold, aluminum, and alloys thereof. In some embodiments, the channel region may be formed to the appropriate transistor configuration, such as forming one or more nanowires/nanoribbons in the channel region for transistors having a nanowire/nanoribbon configuration. Recall that although the structures in FIGS. 2A-I and 3 are shown having a finned non-planar configuration, method 100 of FIG. 1 may be used to form transistors having a planar configuration. The particular channel configurations (e.g., planar, finned, or nanowire/nanoribbon) may be selected based on factors such as the end use or target application or desired performance criteria. Note that the processes 102-120 of method 100 are shown in a particular order in FIG. 1 for ease of description. However, one or more of the processes 102-120 may be performed in a different order or may not be performed at all. For example, box 106 is an optional process that may not be performed if the resulting desired transistor architecture is planar. In another example variation, box 108 may be performed earlier in method 100, depending upon the well doping techniques used. In yet another example variation, a portion of gate processing 110 may be performed later in method 100, such as during a replacement metal gate (RMG) process. Numerous variations on method 100 will be apparent in light of the present disclosure. FIG. 4A illustrates an example integrated circuit including two transistor structures having finned configurations, in accordance with an embodiment. FIG. 4B illustrates an example integrated circuit including two transistor structures having nanowire configurations, in accordance with an embodiment. FIG. 4C illustrates an example integrated circuit including two transistor structures, one having a finned configuration and one having a nanowire configuration, in accordance with an embodiment. The structure in FIGS. 4A-C are similar to the structure of FIG. 2H, except that only two finned regions are shown to better illustrate the channel regions, for ease of discussion. As can be seen in the example structure of FIG. 4A, the original finned configuration was maintained in the channel regions 402. However, the structure of FIG. 4A may also be achieved by replacing the channel region with a finned structure during a replacement gate process (e.g., an RMG process). In such finned configurations, which are also referred to as tri-gate and fin-FET configurations, there are three effective gates—two on either side and one on top—as is known in the field. As can also be seen in the example structure of FIG. 4A, the carbon-based interface region 240 is located between the channel region 402 and the S/D region 252. Note that in this example embodiment, the interface region 240 (including one or more carbon-based interface layers and other optional interface layers as variously described herein) is also located between the channel region 402 and the S/D region 254; however, the interface region 240 is not shown on the other side of the channel region 402 for ease of illustration.

As can be seen in the example structure of FIG. 4B, the channel region was formed into two nanowires or nanoribbons 404. A nanowire transistor (sometimes referred to as a gate-all-around or nanoribbon transistor) is configured similarly to a fin-based transistor, but instead of a finned channel region where the gate is on three sides (and thus, there are three effective gates), one or more nanowires are used and the gate material generally surrounds each nanowire on all sides. Depending on the particular design, some nanowire transistors have, for example, four effective gates. As can be seen in the example structure of FIG. 4B, the transistors each have two nanowires 404, although other embodiments can have any number of nanowires. The nanowires 404 may have been formed while the channel regions were exposed during a replacement gate process (e.g., an RMG process), after the dummy gate is removed, for example. As can also be seen in the example structure of FIG. 4B, the carbon-based interface region 240 is located between the channel region 404 and the S/D region 252. Note that in this example embodiment, the interface region 240 (including one or more carbon-based interface layers and other optional interface layers as variously described herein) is also located between the channel region 404 and the S/D region 254; however, the interface region 240 is not shown on the other side of the channel region 404 for ease of illustration. Although the structure of FIG. 4A and 4B illustrate the transistor configurations being the same per each structure, the channel regions may vary. For example, the structure of FIG. 4C illustrates an example integrated circuit including two transistor structures where one has a finned configuration 402 and the other has a nanowire configuration 404. Numerous variations and configurations will be apparent in light of the present disclosure.

Example System

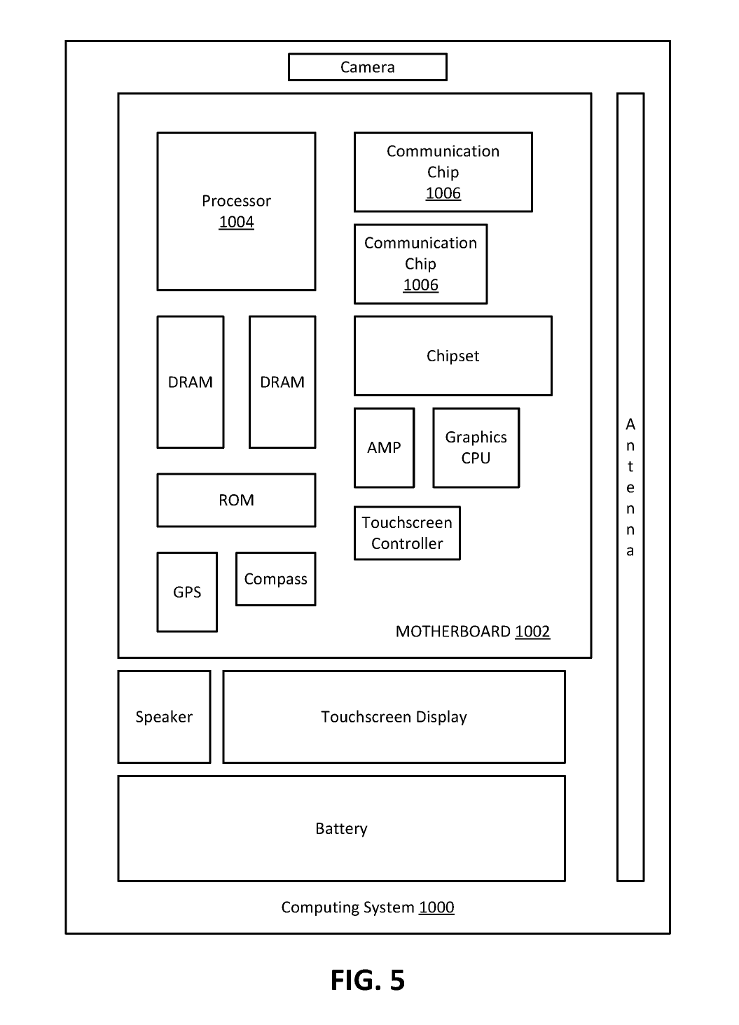

FIG. 5 illustrates a computing system 1000 implemented with integrated circuit structures or devices formed using the techniques disclosed herein, in accordance with various embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or transistor devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or transistor devices formed using the disclosed techniques, as variously described herein.

### Further Example Embodiments

The following examples pertain to further embodiments, from which numerous permutations and configurations will be apparent.

Example 1 is a transistor comprising: a silicon (Si) channel region formed from a portion of a Si substrate; source/drain (S/D) regions comprising one of boron-doped silicon (Si:B) and boron-doped silicon germanium (SiGe:B); and one or more carbon-based interface layers between the channel region and the S/D regions, wherein the one or more carbon-based interface layers comprise a percentage of carbon content that is greater than 0%.

Example 2 includes the subject matter of Example 1, wherein the one or more carbon-based interface layers include a single layer comprising at least 20% carbon.

Example 3 includes the subject matter of Example 2, wherein the single layer has a thickness between the channel region and the corresponding S/D region of 1 to 8 nm.

Example 4 includes the subject matter of Example 2, wherein the single layer has a thickness between the channel region and the corresponding S/D region of approximately 1 nm.

Example 5 includes the subject matter of Example 1, wherein the one or more carbon-based interface layers include a single layer comprising at most 5% carbon.

Example 6 includes the subject matter of Example 5, wherein the single layer has a thickness between the channel region and the corresponding S/D region of 5 to 10 nm.

Example 7 includes the subject matter of any of Examples 1-6, wherein the one or more carbon-based interface layers is a single layer including at least one graded material component.

Example 8 includes the subject matter of any of Examples 1-7, wherein the one or more carbon-based interface layers further comprises at least one of Si and germanium (Ge).

Example 9 includes the subject matter of any of Examples 1-8, wherein the one or more carbon-based interface layers is boron doped.

Example 10 includes the subject matter of any of Examples 1-9, further comprising one or more additional interface layers, the one or more additional interface layers located between the one or more carbon-based interface layers and the S/D regions, wherein the one or more additional layers comprise SiGe:B and the percentage of Ge content in the one or more additional interface layers is greater than or equal to 0.

Example 11 includes the subject matter of Example 10, wherein the percentage of Ge content in the one or more additional interface layers is less than the percentage of Ge content in the S/D regions.

Example 12 includes the subject matter of Example 10, wherein the one or more additional interface layers consists of a single layer of one of Si:B and SiGe:B.

Example 13 includes the subject matter of Example 10, wherein the one or more additional interface layers consist of a first layer comprising Si:B and a second layer comprising SiGe:B.

Example 14 includes the subject matter of Example 10, wherein the one or more additional interface layers comprise a graded SiGe:B layer such that the percentage of Ge content in the graded layer increases from a portion nearest the one or more carbon-based interface layers to a portion nearest the corresponding S/D region.

Example 15 includes the subject matter of any of Examples 1-14, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 16 includes the subject matter of Example 15, wherein substantially the same consists of being within 1 nm in thickness.

Example 17 includes the subject matter of any of Examples 1-16, wherein the transistor geometry includes at least one of a field-effect transistor (FET), metal-oxide-semiconductor FET (MOSFET), tunnel-FET (TFET), planar configuration, finned configuration, fin-FET configuration, tri-gate configuration, nanowire configuration, and nanoribbon configuration.

Example 18 is a complementary metal-oxide-semiconductor (CMOS) device comprising the subject matter of any of Examples 1-17.

Example 19 is a computing system comprising the subject matter of any of Examples 1-18.

Example 20 is a p-type metal-oxide-semiconductor (p-MOS) transistor comprising: an n-type doped silicon (Si) channel region formed from a portion of a Si substrate; epitaxially grown source/drain (S/D) regions comprising one of boron-doped silicon (Si:B) and boron-doped silicon germanium (SiGe:B); and one or more carbon-based interface layers between the channel region and the S/D regions, wherein the one or more carbon-based interface layers comprise a percentage of carbon content that is greater than 0%.

Example 21 includes the subject matter of Example 20, wherein the one or more carbon-based interface layers include a single layer comprising at least 20% carbon

Example 22 includes the subject matter of Example 21, wherein the single layer has a thickness between the channel region and the corresponding S/D region of 1 to 8 nm.

Example 23 includes the subject matter of Example 21, wherein the single layer has a thickness between the channel region and the corresponding S/D region of approximately 1 nm.

Example 24 includes the subject matter of Example 20, wherein the one or more carbon-based interface layers include a single layer comprising at most 5% carbon.

Example 25 includes the subject matter of Example 24, wherein the single layer has a thickness between the channel region and the corresponding S/D region of 5 to 10 nm.

Example 26 includes the subject matter of any of Examples 20-25, wherein the one or more carbon-based interface layers is a single layer including at least one graded material component.

Example 27 includes the subject matter of any of Examples 20-26, wherein the one or more carbon-based interface layers further comprises at least one of Si and germanium (Ge).

Example 28 includes the subject matter of any of Examples 20-27, wherein the one or more carbon-based interface layers is boron doped.

Example 29 includes the subject matter of any of Examples 20-28, further comprising one or more additional interface layers, the one or more additional interface layers located between the one or more carbon-based interface layers and the S/D regions, wherein the one or more additional layers comprise SiGe:B and the percentage of Ge content in the one or more additional interface layers is greater than or equal to 0.

Example 30 includes the subject matter of Example 29, wherein the percentage of Ge content in the one or more additional interface layers is less than the percentage of Ge content in the S/D regions.

Example 31 includes the subject matter of Example 29, wherein the one or more additional interface layers consists of a single layer of one of Si:B and SiGe:B.

Example 32 includes the subject matter of Example 29, wherein the one or more additional interface layers consist of a first layer comprising Si:B and a second layer comprising SiGe:B.

Example 33 includes the subject matter of Example 29, wherein the one or more additional interface layers comprise a graded SiGe:B layer such that the percentage of Ge content in the graded layer increases from a portion nearest the one or more carbon-based interface layers to a portion nearest the corresponding S/D region.

Example 34 includes the subject matter of any of Examples 20-33, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 35 includes the subject matter of Example 34, wherein substantially the same consists of being within 1 nm in thickness.

Example 36 includes the subject matter of any of Examples 20-35, wherein the transistor geometry includes at least one of a planar configuration, finned configuration, fin-FET configuration, tri-gate configuration, nanowire configuration, and nanoribbon configuration.

Example 37 is a complementary metal-oxide-semiconductor (CMOS) device comprising the subject matter of any of Examples 20-36.

Example 38 is a computing system comprising the subject matter of any of Examples 20-37.

Example 39 is a method of forming a transistor, the method comprising: forming a fin in a silicon (Si) substrate; forming a gate stack on the Si fin to define a channel region and source/drain (S/D) regions, the channel located underneath the gate stack and the S/D regions on either side of the channel region; etching the S/D regions to form S/D trenches; depositing one or more carbon-based interface layers in the S/D trenches, wherein the one or more carbon-based interface layers comprise a percentage of carbon content that is greater than 0%; and depositing S/D replacement material over at least a portion of the one or more carbon-based interface layers such that the one or more carbon-based interface layers are between the channel and the S/D regions, the S/D replacement material comprising one of boron-doped silicon (Si:B) and boron-doped silicon germanium (SiGe:B) in the S/D regions.

Example 40 includes the subject matter of Example 39, further comprising doping the Si channel region with an n-type dopant.

Example 41 includes the subject matter of any of Examples 39-40, wherein depositing the SiGe:B replacement S/D regions includes a chemical vapor deposition (CVD) process.

Example 42 includes the subject matter of any of Examples 39-41, wherein the one or more carbon-based interface layers include a single layer comprising at least 20% carbon.

Example 43 includes the subject matter of any of Examples 39-41, wherein the one or more carbon-based interface layers include a single layer comprising at most 5% carbon.

Example 44 includes the subject matter of any of Examples 39-43, further comprising depositing one or more additional interface layers between the one or more carbon-based interface layers and the replacement S/D material, wherein the one or more additional layers comprise SiGe:B and the percentage of Ge content in the one or more additional interface layers is greater than or equal to 0.

Example 45 includes the subject matter of any of Examples 39-44, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 46 includes the subject matter of Example 45, wherein substantially the same consists of being within 1 nm in thickness.

Note that although specific percentages of carbon in the carbon-containing interface layers are provided in the above examples, once the one or more carbon-based interface layers are exposed to anneals, then the carbon may spread out in some manner. Therefore, in some example embodiments, an interface region between a Si channel and epitaxially grown S/D regions may comprise carbon in the range of 1E13 to 3E14 atoms per cm². Also note that although specific thicknesses are provided in the above examples, the carbon deposited in the interface region may occupy a narrower or wider region, depending on the thermal history post carbon deposition. As can be understood based on the present disclosure, the presence of some carbon between a Si channel region and replacement S/D regions of a transistor can provide numerous benefits, including, for example, improving short channel effects. Further note that the techniques variously described herein can be used to form transistors of any suitable geometry or configuration, depending on the end use or target application. For example, some such geometries include field-effect transistor (FET), metal-oxide-semiconductor FET (MOSFET), tunnel-FET (TFET), planar configuration, finned configuration (e.g., tri-gate, fin-FET), nanowire (or nanoribbon or gate-all-around) configuration, just to name a few example geometries. In addition, the techniques may be used to form CMOS transistors/devices/circuits, where the techniques are used to form the p-MOS transistors within the CMOS.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. A transistor comprising:
a body comprising silicon;
a region comprising silicon and boron; and
one or more layers between the body and the region, the one or more layers comprising carbon .

2. The transistor of claim 1, wherein the one or more layers include a single layer comprising at least 20 atomic % carbon.

3. The transistor of claim 2, wherein the single layer has a thickness of approximately 1 nanometer between the body and the region.

4. The transistor of claim 1, wherein the one or more layers include a single layer comprising at most 5 atomic % carbon.

5. The transistor of claim 4, wherein the single layer has a thickness of 5 to 10 nanometers between the body and the region.

6. The transistor of claim 1, wherein the one or more layers consist of a single layer including at least one graded material component.

7. The transistor of claim 1, wherein the one or more layers further comprises at least one of silicon or germanium.

8. The transistor of claim 1, wherein the one or more layers includes boron.

9. The transistor of claim 1, further comprising one or more additional layers, the one or more additional layers between the one or more layers and the region, wherein the one or more additional layers comprise silicon, germanium, and boron.

10. The transistor of claim 9, wherein the one or more additional layers consist of a first layer comprising silicon and boron and a second layer comprising silicon, germanium, and boron.

11. The transistor of claim 9, wherein the germanium content in the one or more additional layers increases from a portion nearest the one or more layers to a portion nearest the region.

12. The transistor of claim 1, wherein a thickness of a portion of the one or more layers between the body and the region is substantially the same as a thickness of a portion of the one or more layers between an underlying substrate and the region.

13. The transistor of claim 12, wherein substantially the same consists of being within 1 nanometer in thickness.

14. The transistor of claim 1, wherein the transistor includes one or more of a planar configuration, finned configuration, fin-FET configuration, tri-gate configuration, nanowire configuration, nanoribbon configuration, or gate-all-around configuration.

15. A complementary metal-oxide-semiconductor (CMOS) device comprising the transistor of claim 1.

16. A computing system comprising the transistor of claim 1.

17. A transistor comprising:
a body comprising silicon;
a region comprising silicon, germanium, and boron, wherein the region is one of a source region or a drain region; and
one or more layers between the body and the region, the one or more layers comprising carbon.

18. The transistor of claim 17, further comprising one or more additional layers, the one or more additional layers between the one or more layers and the region, wherein the one or more additional layers comprise silicon, germanium, and boron.

19. The transistor of claim 17, wherein the body is one of a fin, a nanowire, or a nanoribbon.

20. A method of forming a transistor, the method comprising:
providing a body comprising silicon;
forming one or more layers adjacent the body, the one or more layers comprising carbon; and
forming a region adjacent the one or more layers such that the one or more layers are between the body and the region, the region comprising silicon and boron.

21. The method of claim 20, wherein the body further comprises at least one of phosphorus or arsenic.

22. The method of claim 20, wherein the one or more layers include a single layer comprising at least 20 atomic % carbon.

23. The method of claim 20, wherein the one or more layers include a single layer comprising at most 5 atomic % carbon.

24. The method of claim 20, further comprising forming one or more additional layers between the one or more layers and the region, wherein the one or more additional layers comprise silicon, germanium, and boron.

25. The method of claim 24, wherein a thickness of a portion of the one or more layers between the body and the region is substantially the same as a thickness of a portion of the one or more interface layers between an underlying substrate and the region.
